(19) United States
(12) Patent Application Publication
(10) Pub. No.: US 2007/0092049 A1
(43) Pub. Date: Apr. 26, 2007

(54) Soft-decision phase detector for low signal-to-noise (SNR) phase tracking

(75) Inventors: Tommy Yu, Orange, CA (US); Amy Gayle Hundhausen, Laguna Beach, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/583,717

(22) Filed: Oct. 20, 2006

Related U.S. Application Data
(60) Provisional application No. 60/729,661, filed on Oct. 25, 2005.

(51) Int. Cl. H03D 3/24

(52) U.S. Cl. 375/375

(57) ABSTRACT

A method and apparatus is disclosed for detecting the amount of unknown offset present in a received data stream. The unknown phase offset may offset the phase of the transmitted data stream from the received data stream. A phase detector uses a soft-decision slicer to estimate the content of a modulation transmitted data stream. The soft-decision slicer generates an estimate of the transmitted data stream depending on the location of the received data stream in relation to a transfer function of the soft-decision slicer depending on the modulation scheme of the received data stream. The phase detector uses the estimate of the transmitted data stream to calculate the amount of the unknown phase offset.

### CROSS-REFERENCE TO RELATED APPLICATIONS

This patent application claims priority the benefit of Provisional Patent Application No. 60/729,661, filed Oct. 25, 2005, entitled “Soft-Decision Detector For Low Signal-To-Noise (SNR) Phase Tracking,” which is incorporated herein by reference in its entirety.

### FIELD OF THE INVENTION

The present invention relates generally to phase detectors and more specifically to using a soft-decision based phase detector to estimate an unknown phase offset in a received communication signal.

### BACKGROUND

A digital communication system typically involves transmitting a modulated data stream from a transmitter to a receiver over a communication channel. The communication channel can include a microwave radio link, a satellite channel, a fiber optic cable, or a copper cable to provide some examples. A communication channel contains a propagation medium that the modulated data stream passes through before reception by the receiver.

A propagation delay of the communication channel may cause the phase of the received data stream to differ from the phase of the transmitted data stream. The difference between the phase of the received data stream and the phase of the transmitted data stream is referred to as an unknown phase offset.

The receiver may use a phase detector to estimate the amount of the unknown phase offset. Conventional phase detectors use a hard-decision slicer to estimate the transmitted data stream. In practice, conventional phase detectors often prove unreliable under low signal to noise ratio conditions due to the high probability of errors in the slicer's estimation of the transmitted data stream.

Therefore, what is needed is a phase detector that minimizes the impact of erroneous slicer decisions when estimating unknown phase offsets.

### BRIEF DESCRIPTION OF THE DRAWINGS/FIGURES

The present invention is described with reference to the accompanying drawings. In the drawings, like reference numbers indicate identical or functionally similar elements. Additionally, the left most digit(s) of a reference number identifies the drawing in which the reference number first appears.

FIG. 1 is an illustration of a block diagram of a phase detector.

FIG. 2 is an illustration of a block diagram of a conventional phase detector using a hard-decision slicer.

FIG. 3 is an illustration of a constellation diagram of a quadrature phase shift-keying (QPSK) modulation scheme.

FIG. 4 is an illustration of a transfer function of a conventional hard-decision slicer.

FIG. 5 is an illustration of a block diagram of a phase detector using a soft-decision slicer according to an exemplary embodiment of the present invention.

FIG. 6 is an illustration of a transfer function of a soft-decision slicer according to an exemplary embodiment of the present invention.

FIG. 7 is a flowchart of exemplary operational steps of a phase detector according to an aspect of the present invention.

The present invention will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE INVENTION

The following detailed description of the present invention refers to the accompanying drawings that illustrate exemplary embodiments consistent with this invention. Other embodiments are possible, and modifications may be made to the embodiments within the spirit and scope of the invention. Therefore, the detailed description is not meant to limit the invention. Rather, the scope of the invention is defined by the appended claims.

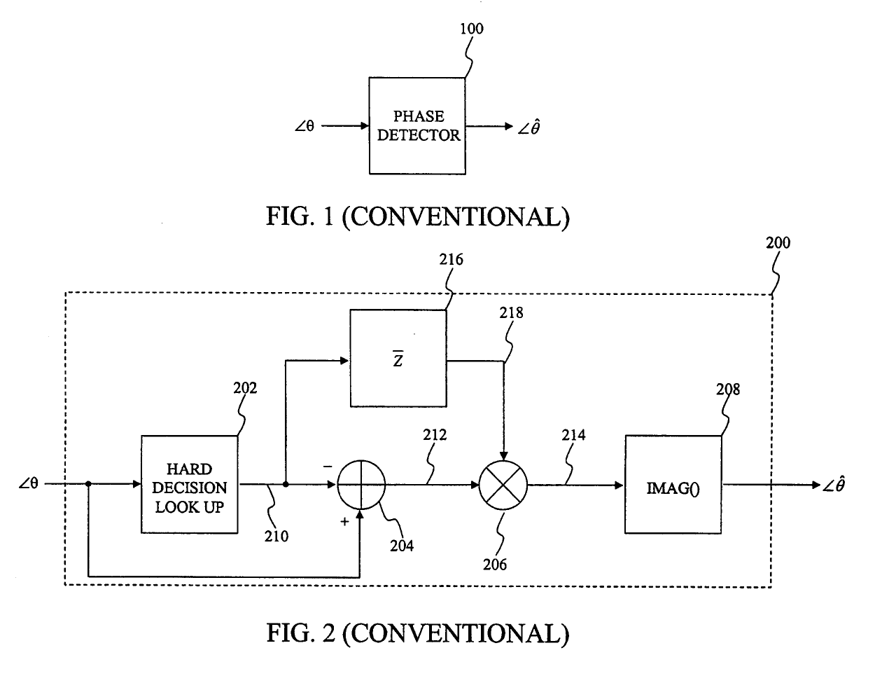

FIG. 1 is an illustration of a block diagram of a phase detector. A phase detector 100 receives a data stream rotated by an unknown phase offset ∠θ. The unknown phase offset ∠θ is the phase difference between the transmitted data stream and the received data stream. The phase difference may be caused by the delay through the propagation medium in the communication channel or by phase noise generated by different components in the communication system, to provide some examples.

The unknown phase offset ∠θ rotates the points in the constellation diagram for the received data stream of the phase detector 100. A constellation diagram is a representation of a digital modulation scheme in the complex or Argand plane. The Argand plane may be considered as a modified cartesian plane, where the x-axis typically represents the real part, and the y-axis typically represents the imaginary part. The points on the constellation diagram located within the Argand plane are a set of modulation symbols that comprise the modulation alphabet.

A receiver in a communications system may use the phase detector 100 to estimate the amount of rotation in the constellation diagram. The phase detector 100 generates an estimate of the phase offset present in the symbol content of the received data stream. More specifically, the phase detector 100 examines the symbol content of the received data stream with the unknown phase offset ∠θ, and uses information derived from the received data stream to generate the phase offset estimate ∠\hat{θ}.

FIG. 2 is an illustration of a block diagram of a phase detector using a hard-decision slicer. A phase detector 200 receives a data stream with an unknown phase offset ∠θ. The unknown phase offset ∠θ rotates the phase of the received data stream relative to the phase of the transmitted data stream. More specifically, propagation delay through the channel medium may cause the phase of the received data stream to differ from the phase of the transmitted data stream. In other words, the unknown phase offset ∠θ represents the amount of unwanted rotation of the transmitted modulated data stream present in the received data stream.

A receiver in a communications system may use the phase detector 200 to estimate the amount of rotation in the constellation diagram. The phase detector 200 generates an estimate of the unknown phase offset present in the symbol content of the received data stream. More specifically, upon receiving the data stream, the phase detector 200 examines the symbol content of the received data stream with the unknown phase offset ∠θ, and uses information derived from the received data stream to generate the phase offset estimate ∠\hat{θ}.

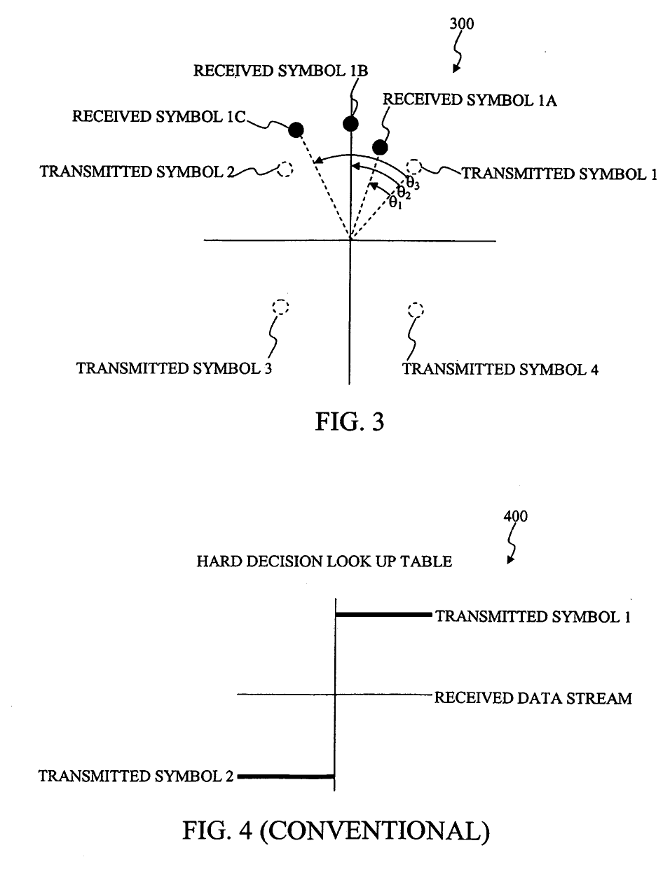

The phase detector 200 includes a conventional hard-decision slicer 202, a summer 204, a multiplier 206, an imaginary number generator 208, and a conjugate module 216. The conventional hard-decision slicer 202 operates upon the received data stream containing the unknown phase offset ∠θ to produce a hard-decision 210. Hard-decision 210 is the symbol in the transmitted symbol constellation that lies closest to the corresponding input symbol. The conventional hard-decision slicer is further explained in FIG. 3 and FIG. 4.

The summer 204 generates a slicer error 212 by comparing the hard-decision 210 with a corresponding input symbol in the received data stream. More specifically, the summer 204 subtracts the hard-decision 210 from the corresponding input symbol in the received data stream to produce the slicer error 212. A conjugate module 216 operates upon the hard-decision 210 to produce a complex conjugate of the hard-decision, denoted as a conjugated hard-decision 218.

The multiplier 206 multiplies the slicer error 212 with conjugated hard-decision 218 to produce a complex phase estimate 214. The complex phase estimate 214 is a complex representation of the estimate of the unknown phase offset ∠θ. The imaginary number generator 208 isolates the imaginary component of the complex phase estimate 214. The imaginary part of the complex phase estimate 214, denoted as the phase detector estimate ∠\hat{θ}, represents the estimate of the unknown phase offset ∠θ present in the symbol content of the received data stream resulting from the communication channel. In an exemplary embodiment, the imaginary number generator 208 is optional. By not including imaginary number generator 208, phase detector 200 may generate a complex representation of the phase offset estimate ∠\hat{θ}. The phase detector 200 may yield reliable estimates of the unknown phase offset ∠θ for high signal-to-noise ratio conditions. However, for lower signal-to-noise ratio conditions, the estimates of the unknown phase offset ∠θ may not be as reliable.

FIG. 3 is an illustration of a constellation diagram 300 of a quadrature phase-shift keying phase shift-keying (QPSK) modulation scheme. In particular, FIG. 3 represents a constellation diagram for a QPSK modulation scheme illustrating the effect of noise on the estimate of the unknown phase offset of ∠θ. The four constellation points of the transmitted data stream shown in FIG. 3 are denoted as transmitted symbol 1 through transmitted symbol 4. Three possible received symbols are denoted as received symbol 1A, received symbol 1B, and received symbol 1C.

A digital communication system typically involves transmitting a modulated data stream from a transmitter to a receiver over a communication channel. A propagation delay of the communication channel may cause the phase of the received data stream to differ from the phase of the transmitted data stream. The difference between the phase of the received data stream and the phase of the transmitted data stream is referred to as an unknown phase offset.

As an example, a propagation delay of the communication channel may cause the phase of the received data stream to differ from the phase of the transmitted data stream by θ₁ assuming a transmitted symbol of 1 and a noise free channel. The unknown phase offset θ₁ rotates the constellation diagram of the received data stream from the constellation diagram of the transmitted symbol by θ₁. In this case, the receiver receives the symbol denoted as received symbol 1A. Those skilled in the arts will recognize that the teachings contained within are applicable to all possible symbols of the transmitted data stream.

Upon receiving the data stream, the conventional hard-decision slicer generates a hard-decision. The hard-decision represents those symbols in the constellation diagram for the transmitted data stream that lie nearest to the examined symbols of the received data stream. For example, the conventional hard-decision slicer sets the hard-decision to be transmitted symbol 1 when the received data stream symbol lies nearest to the transmitted symbol constellation point corresponding to transmitted symbol 1. As shown in FIG. 3, received symbol 1A represents a received data symbol that lies nearest to transmitted symbol 1 with a phase offset of Θ₁. In this scenario, the conventional hard-decision slicer would select transmitted symbol 1 as the hard decision. In other words, because received symbol 1A is closer to transmitted symbol 1 than to transmitted symbols 2, 3, or 4, the conventional hard-decision slicer would select transmitted symbol 1 instead of transmitted symbol 2, 3, or 4 to be the hard decision. As a result, phase detector 200, as shown in FIG. 2, may properly estimate the unknown phase offset as Θ₁.

As another example, a propagation delay of the communication channel may again rotate the phase of the transmitted data stream by Θ₁ assuming a transmitted symbol of 1. The presence of noise may further rotate the transmitted data stream so that the phase of the final received data stream differs from the phase of the transmitted data stream by Θ₂, assuming a transmitted symbol of 1. In this case, the receiver receives the symbol denoted as received symbol 1B.

The conventional hard-decision slicer may generate decision errors that impact the estimate of the unknown phase offset when the constellation point of the received data stream lies near the decision boundary of the hard-decision slicer. The decision boundary of the conventional hard-decision slicer is a point in the Argand plane whereby a constellation point of the received data stream, for example received symbol 1B, is equidistant from the constellation points of the transmitted data stream, for example transmitted symbol 1 and transmitted symbol 2. For the purposes of this example, received symbol 1B represents a received data symbol based on transmitted symbol 1 that lies near the decision boundary of the hard-decision slicer upon its reception. In this case, the conventional hard-decision slicer may not properly estimate the symbol content of the transmitted data stream. In other words, because received symbol 1A is equidistant from transmitted symbol 1 or transmitted symbol 2, the conventional hard-decision slicer may estimate the symbol of the transmitted data stream as either transmitted symbol 1 or transmitted symbol 2 with equal probability. If the slicer selects transmitted symbol 2 as the hard decision, the difference between the actual unknown phase offset and the estimated phase offset is substantial due to the error in the slicer's decision.

As a further example, a propagation delay of the communication channel may again rotate the phase of the transmitted data stream by θ₁ assuming a transmitted symbol of 1. The presence of noise may further rotate the transmitted data stream so that the phase of the final received data stream differs from the phase of the transmitted data stream by θ₃, assuming a transmitted symbol of 1. In this case, the receiver receives the symbol denoted as received symbol 1C.

In this case, the conventional hard-decision slicer will generate decision errors that affect the estimate of the unknown phase offset because the constellation point of the received data stream crosses the decision boundary. For the purposes of this example, received symbol 1C represents a received data symbol based on transmitted symbol 1 that lies nearest to transmitted symbol 2 upon its reception. The conventional hard-decision slicer may not properly estimate the symbol content of the transmitted data stream. In other words, because received symbol 1C is closer to transmitted symbol 2 than transmitted symbol 1, 3, or 4, the conventional hard-decision slicer estimates the symbol of the transmitted data stream as transmitted symbol 2 instead of transmitted symbol 1, 3, or 4. As a result, phase detector 200 as shown in FIG. 2, cannot properly estimate the unknown phase offset θ₁. In this scenario, the difference between the actual unknown phase offset and the estimated phase offset is substantial due to the error in the hard-decision. Operating the receiver in lower signal-to-noise ratio conditions increases the probability for hard slicer errors. The increase in the probability for hard slicer errors diminishes the reliability of the estimated phase offset.

Although the conventional hard-decision slicer is discussed referring to a QPSK modulation scheme, those skilled in the arts will recognize that the teachings contained herein may also be applied to a Binary Phase Shift Keying (BPSK), a 8 Phase Shift Keying (8-PSK), a quadrature amplitude modulation (QAM), or any other suitable modulation scheme.

FIG. 4 is an illustration of a transfer function 400 of a conventional hard-decision slicer. In other words, FIG. 4 represents the transfer function of an exemplary embodiment of the conventional hard-decision slicer 202 presented in FIG. 2.

The conventional hard-decision slicer estimates the content of the transmitted data stream based upon the content of the received data stream. More specifically, the hard-decision slicer selects the transmitted symbol estimate to be the symbol in the transmitted symbol constellation that lies closest to the received symbol. In an exemplary embodiment, the hard-decision slicer may be implemented in the form of a look up table. A look up table is a data structure used to replace a runtime computation with a list of precomputed values. In another exemplary embodiment, the hard-decision slicer may be implemented in the form of a set of comparators to evaluate the polarity of the real and imaginary components of the received symbol in order to select the symbol in the transmitted symbol constellation closest to the received symbol.

The input to output mapping of the hard-decision slicer may be expressed as a single transfer function. In an exemplary embodiment, FIG. 4 illustrates a transfer function of a conventional hard-decision slicer for a BPSK modulation scheme. In this case, when a symbol within the received data stream is positive, the conventional hard-decision slicer selects the hard decision for the symbol within the received data stream to be transmitted symbol 1. Similarly, when a symbol within the received data stream is negative, the conventional hard-decision slicer selects the hard decision for the symbol within the received data stream to be transmitted symbol 2. Further modulation schemes may be used by the conventional hard-decision slicer by incorporating a similar transfer function for each dimension of the modulation scheme. For example, the transfer function of a conventional hard-decision slicer for quadrature phase shift keying (QPSK) may be expressed in two dimensions. In this case, the conventional hard-decision slicer requires two one-dimensional transfer functions, as shown in FIG. 4, to estimate the content of the transmitted data stream. The first one-dimensional transfer function corresponds to the real axis of the Argand plane and another one-dimensional transfer function corresponds to the imaginary axis of the Argand plane.

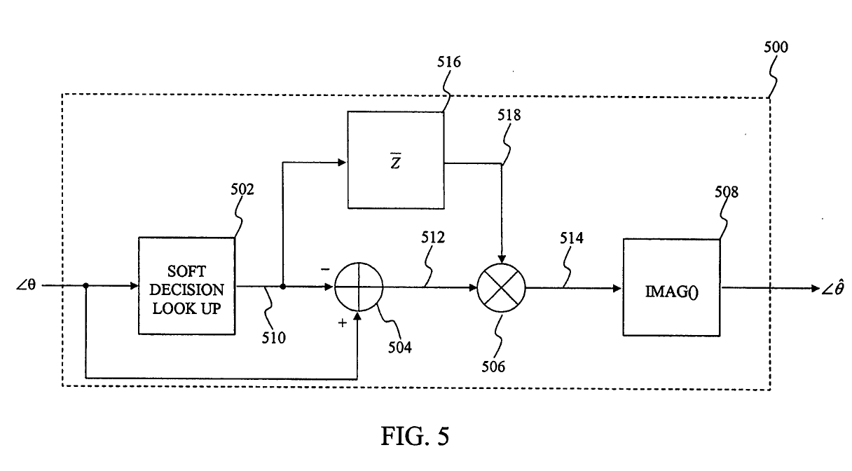

FIG. 5 is an illustration of block diagram of a phase detector 500 using a soft-decision slicer according to an exemplary embodiment of the present invention. A phase detector 500 receives a data stream with an unknown phase offset ∠θ. The unknown phase offset ∠θ rotates the phase of the received data stream relative to the phase of the transmitted data stream. More specifically, propagation delay through the channel medium may cause the phase of the received data stream to differ from the phase of the transmitted data stream. In other words, the unknown phase offset ∠θ represents the amount of unwanted rotation of the transmitted modulated data stream present in the received data stream.

A receiver in a communications system may use the phase detector 500 to estimate the amount of rotation in the constellation diagram. The phase detector 500 generates an estimate of the unknown phase offset present in the symbol content of the received data stream. More specifically, the phase detector 500 examines the symbol content of the received data stream with the unknown phase offset ∠θ, and uses information derived from the received data stream to generate the phase offset estimate ∠\hat{θ}.

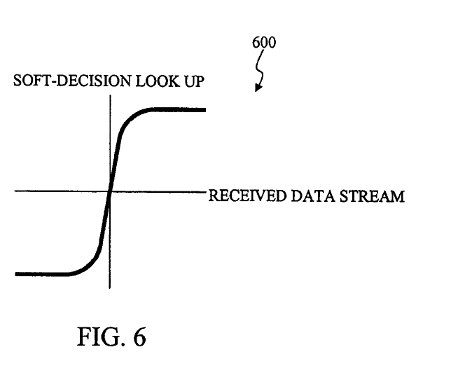

The phase detector 500 includes a soft-decision slicer 502, a summer 504, a multiplier 506, an imaginary number generator 508, and a conjugate module 516. The soft-decision slicer 502 operates upon the received data stream containing the unknown phase offset ∠θ to produce a soft-decision 510. The soft-decision 510 is an estimate of the content of the transmitted modulated data stream. The soft-decision slicer 502 is further explained in FIG. 6.

The summer 504 generates a slicer error 512 by comparing the soft-decision 510 with a corresponding input symbol in the received data stream. More specifically, the summer 504 subtracts the soft-decision 510 from the corresponding input symbol in the received data stream to produce the slicer error 512. A conjugate module 516 operates upon the soft-decision 510 to produce a complex conjugate of the soft-decision, denoted as a conjugated soft-decision 518.

The multiplier 506 multiplies the slicer error 512 with conjugated soft-decision 518 to produce a complex phase estimate 514. The complex phase estimate 514 is a complex representation of the estimate of the unknown phase offset ∠θ. The imaginary number generator 508 isolates the imaginary component of the complex phase estimate 514. The imaginary part of the complex phase estimate 514, denoted as the phase detector estimate ∠\hat{θ}, represents the estimate of the unknown phase offset ∠θ present in the symbol content of the received data stream resulting from the communication channel. In an exemplary embodiment, the imaginary number generator 508 is optional. By not including imaginary number generator 508, phase detector 500 may generate a complex representation of the phase offset estimate ∠\hat{θ}.

FIG. 6 is an illustration of a transfer function 600 of a soft-decision slicer according to an exemplary embodiment of the present invention. The soft-decision slicer generates an estimate of the transmitted data stream. The transfer function defines the mapping between the received input symbols and the soft slicer's estimate of the associated transmitted symbols. More specifically, the soft slicer's estimate of the transmitted symbols is defined as the expected value of the transmitted symbol given the received symbol. In an exemplary embodiment, the soft-decision slicer may be implemented in the form of a look up table.

The transfer function of the soft decision slicer may vary for different modulation schemes. For example, the transfer function of FIG. 6 may represent the soft-decision slicer for either the in phase or the quadrature phase of a QPSK modulated data stream. In this scenario, the transfer function of the soft-decision slicer for a QPSK modulated received data steam r (rₓ,r_{y}) is given by the following equation:

$${d}_{x} = \frac{1}{\sqrt{2}} tanh ( \frac{\sqrt{2} * {r}_{x}}{{σ}^{2}} ) \\ {d}_{y} = \frac{1}{\sqrt{2}} tanh ( \frac{\sqrt{2} * {r}_{y}}{{σ}^{2}} ) \qquad ( 1 )$$

where dₓ represents the transfer function of the soft-decision slicer for the in phase component of a QPSK modulated data stream, and d_{y} represents the transfer function of the soft-decision slicer for the quadrature component of a QPSK modulated data stream, and σ² is the noise variance corresponding to a given signal to noise ratio.

Although FIG. 6 demonstrates the transfer function for one component of a soft-decision slicer for a QPSK modulated data stream, the soft-decision slicer may be implemented for other modulation schemes. For example, in a BPSK modulation scheme, the transfer function of a soft-decision slicer for a received data steam r is given by the following equation:

$$d = \frac{1}{\sqrt{2}} tanh ( \frac{\sqrt{2} * r}{{σ}^{2}} ) \qquad ( 2 )$$

where σ² is the noise variance for a given channel signal to noise ratio. For other modulation schemes, the soft-decision slicer requires two one-dimensional transfer functions to estimate the content of the transmitted data stream, with the first one-dimensional transfer function corresponding to the real axis of the Argand plane and another one-dimensional transfer function corresponding to the imaginary axis of the Argand plane. For an 8-PSK modulation scheme, the transfer function of a soft-decision slicer for a received data steam r (rₓ,r_{y}) is given by equation (3):

$${d}_{x} = \frac{\begin{matrix}a * sinh ( \frac{2 * a * {r}_{x}}{{σ}^{2}} ) * cosh ( \frac{2 * b * {r}_{y}}{{σ}^{2}} ) + \\ b * sinh ( \frac{2 * b * {r}_{x}}{{σ}^{2}} ) * cosh ( \frac{2 * a * {r}_{y}}{{σ}^{2}} )\end{matrix}}{\begin{matrix}cosh ( \frac{2 * a * {r}_{x}}{{σ}^{2}} ) * cosh ( \frac{2 * b * {r}_{y}}{{σ}^{2}} ) + \\ cosh ( \frac{2 * b * {r}_{x}}{{σ}^{2}} ) * cosh ( \frac{2 * a * {r}_{y}}{{σ}^{2}} )\end{matrix}} \\ {d}_{y} = \frac{\begin{matrix}a * sinh ( \frac{2 * a * {r}_{y}}{{σ}^{2}} ) * cosh ( \frac{2 * b * {r}_{x}}{{σ}^{2}} ) + \\ b * sinh ( \frac{2 * b * {r}_{y}}{{σ}^{2}} ) * cosh ( \frac{2 * a * {r}_{x}}{{σ}^{2}} )\end{matrix}}{\begin{matrix}cosh ( \frac{2 * a * {r}_{y}}{{σ}^{2}} ) * cosh ( \frac{2 * b * {r}_{x}}{{σ}^{2}} ) + \\ cosh ( \frac{2 * b * {r}_{y}}{{σ}^{2}} ) * cosh ( \frac{2 * a * {r}_{x}}{{σ}^{2}} )\end{matrix}} \qquad ( 3 )$$

where

$$a = sin ( \frac{π}{8} ) , \\ b = cos ( \frac{π}{8} ) ,$$

and σ² is the noise variance for a given channel signal to noise ratio. For a 16-QAM modulation scheme, the transfer function of a soft-decision slice for a received data steam r (rₓ,r_{y}) is given by the following equation:

$${d}_{x} = \frac{sinh ( \frac{2 * {r}_{x}}{{σ}^{2}} ) + 3 * exp ( \frac{- 8}{{σ}^{2}} ) * sinh ( \frac{6 * {r}_{x}}{{σ}^{2}} )}{cosh ( \frac{2 * {r}_{x}}{{σ}^{2}} ) + exp ( \frac{- 8}{{σ}^{2}} ) * cosh ( \frac{6 * {r}_{x}}{{σ}^{2}} )} \\ {d}_{y} = \frac{sinh ( \frac{2 * {r}_{y}}{{σ}^{2}} ) + 3 * exp ( \frac{- 8}{{σ}^{2}} ) * sinh ( \frac{6 * {r}_{y}}{{σ}^{2}} )}{cosh ( \frac{2 * {r}_{y}}{{σ}^{2}} ) + exp ( \frac{- 8}{{σ}^{2}} ) * cosh ( \frac{6 * {r}_{y}}{{σ}^{2}} )} \qquad ( 4 )$$

where σ² is the noise variance for a given channel signal to noise ratio. Equations 1, 2, 3, and 4 are further described in “Mitigation of Error Propagation in Decision Feedback Equalization,” Jaiganesh Balakrishman, August 1999, which is incorporated herein by reference in its entirety.

The soft-decision phase detector, as shown in FIGS. 5 and 6, may yield better performance than the hard-decision phase detector, as shown in FIGS. 2 and 3, at lower signal-to-noise ratios. For a hard-decision slicer, any received symbol that lies within the decision boundaries surrounding the associated transmitted symbol generates a slicer error value of zero. However, any received symbol that crosses the decision boundaries and approaches the adjacent transmitted symbol generates a slicer error with a magnitude that is the distance between two constellation points. By contrast, a soft-decision slicer produces a continuous set of slicer error values based on the soft-decision transfer function. The soft-decision slicer balances a tradeoff between the penalty for receiving a symbol that is located far from the transmitted symbol and the ability to avoid slicer error penalties when the received symbol is located close to the transmitted symbol.

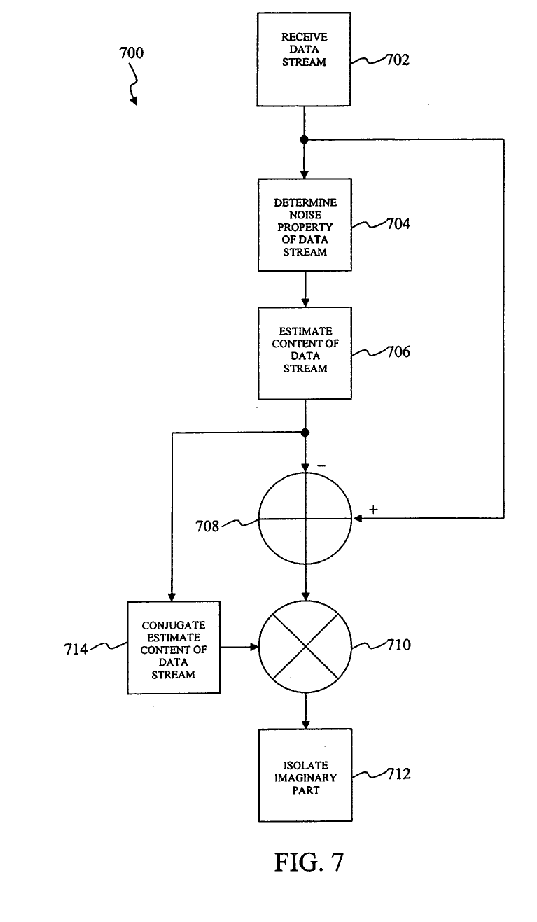

FIG. 7 is a flowchart 700 of exemplary operational steps of a phase detector according to an aspect of the present invention. The invention is not limited to this operational description. Rather, it will be apparent to persons skilled in the relevant art(s) from the teachings herein that other operational control flows are within the scope and spirit of the present invention. The following discussion describes the steps in FIG. 7.

At step 702, a data stream with an unknown phase offset ∠θ is received by the phase detector. The unknown phase offset ∠θ may rotate the phase of the received data stream relative to the transmitted data stream. More specifically, a propagation delay through the channel medium may cause the phase of the received data stream to differ from the phase of the transmitted data stream.

At step 704, a noise property of the data stream is determined. For example, the noise variance for a given channel signal to noise ratio, denoted as σ² in equation 1, for a QPSK modulated data stream may be determined.

At step 706, the symbol content of the transmitted data stream is estimated by the phase detector. A decision device such as conventional hard-decision slicer 202 or a soft-decision slicer 502 estimates the content of the transmitted data stream based upon both the symbol content of the received data stream and an associated transfer function.

At step 708, the estimate of the symbol content of the transmitted data stream is subtracted from the symbol content of the received data stream. The phase detection circuit uses a summing module, such as summer 204, to subtract the estimate of the symbol content of the transmitted data stream from the symbol content of the received data stream.

At step 714, the estimate of the symbol content of the transmitted data stream is conjugated.

At step 710, the output from step 708 is multiplied by the conjugate of the estimate of the symbol content of the transmitted data stream from step 714. A multiplier, such as multiplier 206, multiplies the conjugate of the estimate of the symbol content of the transmitted data stream by the output from step 708 to generate a complex signal that is an estimate of the unknown phase offset ∠θ. The unknown phase offset ∠θ may rotate constellation points in the constellation diagram of the received data stream relative to the constellation points of the transmitted modulated data stream. For example, the unknown phase offset in the received data stream for a quadrature phase-shift keying (QPSK) communication signal may rotate the four constellation points an amount related to the unknown phase offset ∠θ.

At step 712, the imaginary component of the derotated output is isolated to produce the phase detector estimate ∠\hat{θ}. More specifically, the multiplier output from step 710 may be separated into a real component and an imaginary component within the Argand plane. An imaginary number generator, such as the imaginary number generator 208, operates on the multiplier output by isolating the imaginary component of the multiplier output. The imaginary part of the multiplier output represents an estimate of the unknown phase offset ∠θ present in the symbol content of the received data stream resulting from the communication channel.

### CONCLUSION

While various embodiments of the present invention have been described above, it should be understood that they have been presented by way of example, and not limitation. It will be apparent to persons skilled in the relevant arts that various changes in form and detail can be made therein without departing from the spirit and scope of the invention. Thus the present invention should not be limited by any of the above-described exemplary embodiments, but should be defined only in accordance with the following claims and their equivalents.

What is claimed is:

1. A phase detector comprising:
a soft-decision slicer coupled to an input of the phase detector;
an adder coupled to an output of the soft-decision slicer and the input of the phase detector;
a multiplier coupled between an output of the adder and an output of a conjugate module;
the conjugate module coupled between the output of the soft-decision slicer and the multiplier; and
an imaginary number generator coupled to an output of the multiplier.

2. The phase detector of claim 1, wherein the input is a quadrature phase-shift keyed (QPSK) data stream having an in phase component rₓ and a quadrature phase component r_{y}.

3. The phase detector of claim 2, wherein a transfer function of the soft-decision slicer for the input is given by the equation:
$${d}_{x} = \frac{1}{\sqrt{2}} tanh ( \frac{\sqrt{2} * {r}_{x}}{{σ}^{2}} )$$
$${d}_{y} = \frac{1}{\sqrt{2}} tanh ( \frac{\sqrt{2} * {r}_{y}}{{σ}^{2}} ) ,$$
wherein dₓ represents a transfer function of the soft-decision slicer for the in phase component of the input, and d_{y} represents a transfer function of the soft-decision slicer for the quadrature component of the input, and σ² is a noise variance for a given channel signal to noise ratio.

4. The phase detector of claim 1, wherein the input is an 8 Phase Shift Keyed (8-PSK) data stream having an in phase component rₓ and a quadrature phase component r_{y}.

5. The phase detector of claim 4, wherein a transfer function of the soft-decision slicer for the input r is given by the equation:
$${d}_{x} = \frac{\begin{matrix}a * sinh ( \frac{2 * a * {r}_{x}}{{σ}^{2}} ) * cosh ( \frac{2 * b * {r}_{y}}{{σ}^{2}} ) + \\ b * sinh ( \frac{2 * b * {r}_{x}}{{σ}^{2}} ) * cosh ( \frac{2 * a * {r}_{y}}{{σ}^{2}} )\end{matrix}}{\begin{matrix}cosh ( \frac{2 * a * {r}_{x}}{{σ}^{2}} ) * cosh ( \frac{2 * b * {r}_{y}}{{σ}^{2}} ) + \\ cosh ( \frac{2 * b * {r}_{x}}{{σ}^{2}} ) * cosh ( \frac{2 * a * {r}_{y}}{{σ}^{2}} )\end{matrix}}$$
$${d}_{y} = \frac{\begin{matrix}a * sinh ( \frac{2 * a * {r}_{y}}{{σ}^{2}} ) * cosh ( \frac{2 * b * {r}_{x}}{{σ}^{2}} ) + \\ b * sinh ( \frac{2 * b * {r}_{y}}{{σ}^{2}} ) * cosh ( \frac{2 * a * {r}_{x}}{{σ}^{2}} )\end{matrix}}{\begin{matrix}cosh ( \frac{2 * a * {r}_{y}}{{σ}^{2}} ) * cosh ( \frac{2 * b * {r}_{x}}{{σ}^{2}} ) + \\ cosh ( \frac{2 * b * {r}_{y}}{{σ}^{2}} ) * cosh ( \frac{2 * a * {r}_{x}}{{σ}^{2}} )\end{matrix}} ,$$
wherein
$$a = sin ( \frac{π}{8} ) , \\ b = cos ( \frac{π}{8} ) ,$$
represents a transfer function of the soft-decision slicer for the in phase component of the input, and d_{y} represents a transfer function of the soft-decision slicer for the quadrature component of the input, and σ² is a noise variance for a given channel signal to noise ratio.

6. The phase detector of claim 1, wherein the input is a quadrature amplitude modulated (QAM) data stream having an in phase component rₓ and a quadrature phase component r_{y}.

7. The phase detector of claim 6, wherein a transfer function of the soft-decision slicer for the input is given by the equation:
$${d}_{x} = \frac{sinh ( \frac{2 * {r}_{x}}{{σ}^{2}} ) + 3 * exp ( \frac{- 8}{{σ}^{2}} ) * sinh ( \frac{6 * {r}_{x}}{{σ}^{2}} )}{cosh ( \frac{2 * {r}_{x}}{{σ}^{2}} ) + exp ( \frac{- 8}{{σ}^{2}} ) * cosh ( \frac{6 * {r}_{x}}{{σ}^{2}} )}$$
$${d}_{y} = \frac{sinh ( \frac{2 * {r}_{y}}{{σ}^{2}} ) + 3 * exp ( \frac{- 8}{{σ}^{2}} ) * sinh ( \frac{6 * {r}_{y}}{{σ}^{2}} )}{cosh ( \frac{2 * {r}_{y}}{{σ}^{2}} ) + exp ( \frac{- 8}{{σ}^{2}} ) * cosh ( \frac{6 * {r}_{y}}{{σ}^{2}} )} ,$$
wherein dₓ represents a transfer function of the soft-decision slicer for the in phase component of the input, and d_{y} represents a transfer function of the soft-decision slicer for the quadrature component of the input, and σ² is a noise variance for a given channel signal to noise ratio.

8. The phase detector of claim 1, wherein a phase of the input is offset from a phase of a transmitted modulated data stream by an unknown amount.

9. The phase detector of claim 8, wherein the output of the phase detector is an estimate of the amount of offset between the input and the transmitted modulated data stream.

10. The phase detector of claim 1, wherein the soft-decision slicer estimates the content of the transmitted data stream based on a noise content of the input.

11. The phase detector of claim 1, wherein the soft-decision slicer estimates the content of the transmitted data stream based on a noise variance for a given channel signal to noise ratio.

12. A method to estimate an unknown phase offset between a received data stream and a transmitted received data stream comprising the steps:
receiving the data stream with an unknown phase offset;
determining a noise property of the input data stream
estimating the content of the associated transmitted data stream
subtracting the estimate of the transmitted data stream from the received data stream to produce a slicer error; and
multiplying the slicer error by a conjugate of the estimate of the transmitted symbol stream.

13. The method of claim 12, further comprising the step of:
isolating an imaginary component of the multiplier output.

14. The method of claim 12, wherein the received data stream is a quadrature phase-shift keyed (QPSK) modulated having an in phase component rₓ and a quadrature phase component r_{y}.

15. The method of claim 13, wherein the step of estimating the symbol content of the transmitted symbol stream further comprises the step of:
estimating the content of the transmitted data stream according to a position of the received data stream in relation to a transfer function for a soft-decision slicer, wherein the transfer function is given by the equation:
$${d}_{x} = \frac{1}{\sqrt{2}} tanh ( \frac{\sqrt{2} * {r}_{x}}{{σ}^{2}} )$$
$${d}_{y} = \frac{1}{\sqrt{2}} tanh ( \frac{\sqrt{2} * {r}_{y}}{{σ}^{2}} ) ,$$
wherein dₓ represents a transfer function of the soft-decision slicer for the in phase component of the received data stream, and d_{y} represents a transfer function of the soft-decision slicer for the quadrature component of the received data stream, and σ² is a noise variance for a given channel signal to noise ratio.

16. The method of claim 13, wherein the received data stream is 8 Phase Shift Keyed (8-PSK) modulated having an in phase component rₓ and a quadrature phase component r_{y}.

17. The method of claim 16, wherein the step of estimating the content of the transmitted symbol stream further comprises the step of:
estimating the content of the transmitted symbol stream according to a position of the received data stream in relation to a transfer function for a soft-decision slicer, wherein the transfer function is given by the equation:
$${d}_{x} = \frac{\begin{matrix}a * sinh ( \frac{2 * a * {r}_{x}}{{σ}^{2}} ) * cosh ( \frac{2 * b * {r}_{y}}{{σ}^{2}} ) + \\ b * sinh ( \frac{2 * b * {r}_{x}}{{σ}^{2}} ) * cosh ( \frac{2 * a * {r}_{y}}{{σ}^{2}} )\end{matrix}}{\begin{matrix}cosh ( \frac{2 * a * {r}_{x}}{{σ}^{2}} ) * cosh ( \frac{2 * b * {r}_{y}}{ {σ}^{2}} ) + \\ cosh ( \frac{2 * b * {r}_{x}}{{σ}^{2}} ) * cosh ( \frac{2 * a * {r}_{y}}{{σ}^{2}} )\end{matrix}}$$
$${d}_{y} = \frac{\begin{matrix}a * sinh ( \frac{2 * a * {r}_{y}}{{σ}^{2}} ) * cosh ( \frac{2 * b * {r}_{x}}{{σ}^{2}} ) + \\ b * sinh ( \frac{2 * b * {r}_{y}}{{σ}^{2}} ) * cosh ( \frac{2 * a * {r}_{x}}{{σ}^{2}} )\end{matrix}}{\begin{matrix}cosh ( \frac{2 * a * {r}_{y}}{{σ}^{2}} ) * cosh ( \frac{2 * b * {r}_{x}}{{σ}^{2}} ) + \\ cosh ( \frac{2 * b * {r}_{y}}{{σ}^{2}} ) * cosh ( \frac{2 * a * {r}_{x}}{{σ}^{2}} )\end{matrix}} ,$$
wherein
$$a = sin ( \frac{π}{8} ) , b = cos ( \frac{π}{8} ) ,$$
dₓ represents a transfer function of the soft-decision slicer for the in phase component of the received data stream, and d_{y} represents a transfer function of the soft-decision slicer for the quadrature component of the received data stream, and σ² is a noise variance for a given channel signal to noise ratio.

18. The method of claim 13, wherein the received data stream is quadrature amplitude (QAM) modulated having an in phase component rₓ and a quadrature phase component r_{y}.

19. The method of claim 18, wherein the step of estimating the content of the transmitted symbol stream further comprises the step of:
estimating the content of the transmitted symbol stream according to a position of the received data stream in relation to a transfer function for a soft-decision slicer, wherein the transfer function is given by the equation:
$${d}_{x} = \frac{sinh ( \frac{2 * {r}_{x}}{{σ}^{2}} ) + 3 * exp ( \frac{- 8}{{σ}^{2}} ) * sinh ( \frac{6 * {r}_{x}}{{σ}^{2}} )}{cosh ( \frac{2 * {r}_{x}}{{σ}^{2}} ) + exp ( \frac{- 8}{{σ}^{2}} ) * cosh ( \frac{6 * {r}_{x}}{{σ}^{2}} )}$$
$${d}_{y} = \frac{sinh ( \frac{2 * {r}_{y}}{{σ}^{2}} ) + 3 * exp ( \frac{- 8}{{σ}^{2}} ) * sinh ( \frac{6 * {r}_{y}}{{σ}^{2}} )}{cosh ( \frac{2 * {r}_{y}}{{σ}^{2}} ) + exp ( \frac{- 8}{{σ}^{2}} ) * cosh ( \frac{6 * {r}_{y}}{{σ}^{2}} )} ,$$
wherein dₓ represents a transfer function of the soft-decision slicer for the in phase component of the received data stream, and d_{y} represents a transfer function of the soft-decision slicer for the quadrature component of the received data stream, and σ² is a noise variance for a given channel signal to noise ratio.

20. The method of claim 12, wherein the step of estimating the content of the transmitted data stream further comprises:
estimating the content of the transmitted data stream using a soft-decision slicer to compare the received data stream to a corresponding transfer function, wherein the corresponding transfer function depends on a modulation scheme of the transmitted data stream.

21. The method of claim 12, wherein the step estimating the content of the transmitted data stream further comprises:
estimating the content of the transmitted data stream based on a noise content of the received data stream.
